(19) United States
(12) Patent Application Publication
(10) Pub. No.: US 2016/0191079 A1
(43) Pub. Date: Jun. 30, 2016

(54) Low Dynamic Power Check Node Processor For Low Density Parity Check Decoder

(71) Applicant: Avago Technologies General IP (Singapore) Pte. Ltd., SG (SG)

(72) Inventors: Qi Zuo, Shanghai (CN); Shu Li, San Jose, CA (US); Dan Liu, Shanghai (CN)

(21) Appl. No.: 14/583,080

(22) Filed: Dec. 24, 2014

(51) Int. Cl. H03M 13/11; H03M 13/00

(52) U.S. Cl. CPC H03M 13/1131; H03M 13/616

(57) ABSTRACT

A low density parity check decoder includes a variable node processor operable to generate variable node to check node messages and to calculate perceived values based on check node to variable node messages, a saturation circuit operable to reduce a precision in the variable node to check node messages, and a check node processor operable to generate the check node to variable node messages based on the variable node to check node messages at least in part by finding a minimum value, an index of the minimum value and a next minimum value of Q values in the variable node to check node messages. The check node processor includes a switching circuit operable to update the minimum and the next minimum values and is operable to disable the switching circuit based at least in part on a comparison between the Q values and the next minimum value.

### FIELD OF THE INVENTION

Various embodiments of the present invention provide systems and methods for low density parity check decoding.

### BACKGROUND

Various data processing systems have been developed including storage systems, cellular telephone systems, and radio transmission systems. In such systems data is transferred from a sender to a receiver via some medium. For example, in a storage system, data is sent from a sender (i.e., a write function) to a receiver (i.e., a read function) via a storage medium. As information is stored and transmitted in the form of digital data, errors are introduced that, if not corrected, can corrupt the data and render the information unusable. The effectiveness of any transfer is impacted by any losses in data caused by various factors. Many types of error checking systems have been developed to detect and correct errors in digital data. For example, parity bits can be added to groups of data bits, ensuring that the groups of data bits (including the parity bits) have either even or odd numbers of ones, and used in error correction systems such as Low Density Parity Check (LDPC) decoders.

### BRIEF SUMMARY

Some embodiments of the present invention provide a low density parity check decoder including a variable node processor operable to generate variable node to check node messages and to calculate perceived values based on check node to variable node messages, a saturation circuit operable to reduce a precision in the variable node to check node messages, and a check node processor operable to generate the check node to variable node messages based on the variable node to check node messages at least in part by finding a minimum value, an index of the minimum value and a next minimum value of Q values in the variable node to check node messages. The check node processor includes a switching circuit operable to update the minimum and the next minimum values and is operable to disable the switching circuit based at least in part on a comparison between the Q values and the next minimum value.

This summary provides only a general outline of some embodiments according to the present invention. Many other embodiments of the present invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals are used throughout several figures to refer to similar components.

FIG. 1 depicts a Tanner graph of a low density parity check code that can be decoded in a low density parity check decoder with a low dynamic power check node processor in accordance with one or more embodiments of the present invention;

FIG. 2 depicts a single path non-binary min-sum based layered low density parity check decoder with a low dynamic power check node processor in accordance with one or more embodiments of the present invention;

FIG. 3 depicts a low dynamic power check node processor for use in a min-sum based low density parity check decoder with a single data path such as that of FIG. 2 in accordance with one or more embodiments of the present invention;

FIG. 4 depicts a dual path non-binary min-sum based layered low density parity check decoder with a low dynamic power check node processor in accordance with one or more embodiments of the present invention;

FIG. 5 depicts a low dynamic power check node processor for use in a min-sum based low density parity check decoder with a dual data path such as that of FIG. 4 in accordance with one or more embodiments of the present invention;

FIG. 6 depicts a flow diagram of an operation for non-binary layered low density parity check decoding with a low dynamic power check node processor in accordance with one or more embodiments of the present invention;

FIG. 7 depicts a block diagram of a read channel with a low density parity check decoding with a low dynamic power check node processor in accordance with one or more embodiments of the present invention;

FIG. 8 depicts a storage system including a non-binary layered low density parity check decoder with normalized input and output in accordance with one or more embodiments of the present invention;

FIG. 9 depicts a wireless communication system including a low density parity check decoder with a low dynamic power check node processor in accordance with one or more embodiments of the present invention; and

FIG. 10 depicts another storage system including a data processing circuit having a low density parity check decoder with a low dynamic power check node processor in accordance with one or more embodiments of the present invention.

### DETAILED DESCRIPTION OF THE INVENTION

Embodiments of the present invention are related to a min-sum based low density parity check decoder with a low dynamic power check node processor, which can save dynamic power by reducing circuit switching activities as it calculates minimum and next minimum values in variable node to check node messages. In some embodiments, the check node processor disclosed herein is embodied in a non-binary layered low density parity check decoder. Low density parity check technology is applicable to transmission of information over virtually any channel or storage of information on virtually any media. Transmission applications include, but are not limited to, optical fiber, radio frequency channels, wired or wireless local area networks, digital subscriber line technologies, wireless cellular, Ethernet over any medium such as copper or optical fiber, cable channels such as cable television, and Earth-satellite communications. Storage applications include, but are not limited to, hard disk drives, compact disks, digital video disks, magnetic tapes and memory devices such as DRAM, NAND flash, NOR flash, other non-volatile memories and solid state drives.

A low density parity check code is defined by a sparse parity check matrix H of size m×n, where m<n. A codeword c of length n satisfies all the m parity check equations defined by H, i.e., cH^{T}=0, where 0 is a zero vector. Decoder convergence is checked by determining whether the syndrome s=cH^{T} is all zero. The syndrome is a vector of length m, with each bit corresponding to a parity check. A zero bit in a syndrome means the check is satisfied, while a non-zero bit in the syndrome is an unsatisfied check (USC). By definition, a codeword has syndrome s=0. A non-codeword has a non-zero syndrome.

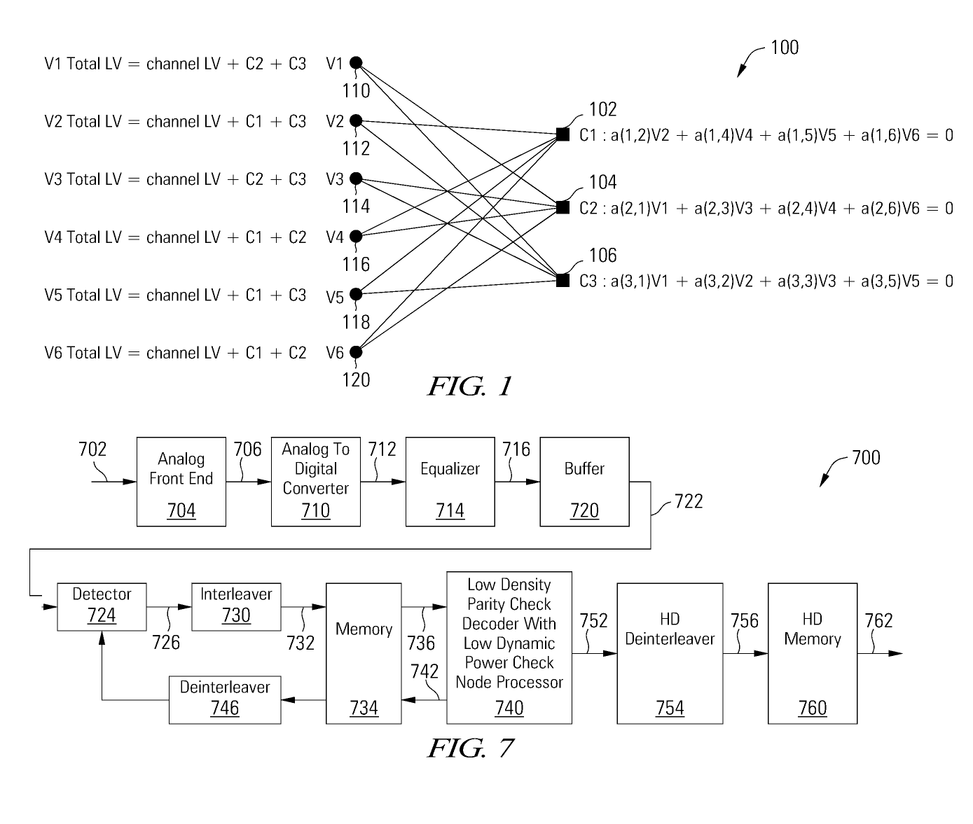

Low density parity check codes are also known as graph-based codes with iterative decoding algorithms, which can be visually represented in a Tanner graph 100 as illustrated in FIG. 1. In a low density parity check decoder, multiple parity checks are performed in a number of check nodes 102, 104 and 106 for a group of variable nodes 110, 112, 114, 116, 118, and 120. The connections (or edges) between variable nodes 110-120 and check nodes 102-106 are selected as the low density parity check code is designed, balancing the strength of the code against the complexity of the decoder required to execute the low density parity check code as data is obtained. The number and placement of parity bits in the group are selected as the low density parity check code is designed. Messages are passed between connected variable nodes 110-120 and check nodes 102-106 in an iterative process, passing beliefs about the values that should appear in variable nodes 110-120 to connected check nodes 102-106. Parity checks are performed in the check nodes 102-106 based on the messages and the results are returned to connected variable nodes 110-120 to update the beliefs if necessary.

In a non-binary low density parity check decoder, variable nodes 110-120 contain symbols from a Galois Field, a finite field GF(p^{k}) that contains a finite number of elements, characterized by size p^{k} where p is a prime number and k is a positive integer. Messages representing variable node values in the non-binary low density parity check decoders are multi-dimensional vectors, containing likelihood values representing the probability that the sending variable node contains a particular value. The term “likelihood value” is used herein to refer to a likelihood or probability that a symbol has a particular value, whether it is represented as a plain-likelihood probability value, a log likelihood ratio (LLR) value, or any other representation of a likelihood.

The connections between variable nodes 110-120 and check nodes 102-106 can be presented in matrix form, where columns represent variable nodes, rows represent check nodes, and a random non-zero element a(i,j) from the Galois Field at the intersection of a variable node column and a check node row indicates a connection between that variable node and check node and provides a permutation for messages between that variable node and check node:

$$H = [ \begin{matrix}0 & a ( 1 , 2 ) & 0 & a ( 1 , 4 ) & a ( 1 , 5 ) & a ( 1 , 6 ) \\ a ( 2 , 1 ) & 0 & a ( 2 , 3 ) & a ( 2 , 4 ) & 0 & a ( 2 , 6 ) \\ a ( 3 , 1 ) & a ( 3 , 2 ) & a ( 3 , 3 ) & 0 & a ( 3 , 5 ) & 0\end{matrix} ]$$

For example, in some embodiments of a GF(4) decoder, each Galois field element a(i,j) specifies a shift for the corresponding circulant matrix of 0, 1, 2 or 3.

The non-binary layered low density parity check decoder uses quasi-cyclic codes in which the parity check H matrix is a matrix of circulant sub-matrices, cyclically shifted versions of identity matrices and null matrices with different cyclical shifts specified by the H matrix non-zero entry values a(i,j). Each circulant P_{i,j} is a p×p sub-matrix with the form:

$${P}_{i , j} = [ \begin{matrix}0 & α & 0 & … & 0 \\ 0 & 0 & α & … & 0 \\ ⋮ & ⋮ & ⋮ & ⋱ & ⋮ \\ 0 & 0 & 0 & … & α \\ α & 0 & 0 & … & 0\end{matrix} ]$$

where entry value α is an element over the Galois Field GF(2^{m}), which has 2^{m-1} possible values.

In some embodiments, the entry value α is randomly selected from the Galois Field. The entry value α provides a permutation for messages between the variable node and check node connected by the entry, where a multiplication in the Galois Field of the message by the current layer entry value is performed. This permutation, performed by the variable node unit or variable node processor in the non-binary layered low density parity check decoder with normalized input and output, is also referred to herein as rearranging. Similarly, when messages are passed back from a check node to a variable node, the messages are inverse-rearranged by the previous layer entry value, where a division in the Galois Field of the message by the current layer entry value is performed.

By providing multiple check nodes 102-106 for the group of variable nodes 110-120, redundancy in error checking is provided, enabling errors to be corrected as well as detected. Each check node 102-106 performs a parity check on bits or symbols passed as messages from its neighboring (or connected) variable nodes. In the example low density parity check code corresponding to the Tanner graph 100 of FIG. 1, check node 102 checks the parity of variable nodes 112, 116, 118 and 120. Perceived values of a variable node are updated based on the parity check results from connected check nodes. For example, the perceived value or likelihood value (LV) of variable node 110 is updated based on the channel likelihood value or previous likelihood value, along with the check node messages (C2, C3) from connected check nodes 104, 106. Values are passed back and forth between connected variable nodes 110-120 and check nodes 102-106 in an iterative process until the low density parity check code converges on a value for the group of data and parity bits in the variable nodes 110-120, or until a maximum number of iterations is reached. For example, variable node 110 passes messages to check nodes 104 and 106, referred to herein as variable node to check node messages or V2C messages. Check node 102 passes messages back to variable nodes 112, 116, 118 and 120, referred to herein as check node to variable node messages or C2V messages. The messages between variable nodes 110-120 and check nodes 102-106 are probabilities or beliefs, thus the low density parity check decoding algorithm is also referred to as a belief propagation algorithm. Each message from a node represents the probability that a bit or symbol has a certain value based on the current value of the node and on previous messages to the node.

A message from a variable node to any particular neighboring check node is computed using any of a number of algorithms based on the current value of the variable node and the last messages to the variable node from neighboring check nodes, except that the last message from that particular check node is omitted from the calculation to prevent positive feedback. Similarly, a message from a check node to any particular neighboring variable node is computed based on the current value of the check node and the last messages to the check node from neighboring variable nodes, except that the last message from that particular variable node is omitted from the calculation to prevent positive feedback. As local decoding iterations are performed in the system, messages pass back and forth between variable nodes 110-120 and check nodes 102-106, with the values in the nodes 102-120 being adjusted based on the messages that are passed, until the values converge and stop changing or until a maximum number of iterations is reached.

In non-binary layered low density parity check decoder, the parity check H matrix is partitioned into L layers, with the H matrix being processed row by row and the circulants being processed layer by layer. As the rows are processed, the column results are updated based on each row result. Layered decoding can reduce the time to converge on a result in the decoder in some cases.

Likelihood values can be represented either in normalized format or absolute format in the non-binary layered low density parity check decoder with normalized input and output. In the absolute or non-normalized format, a likelihood value for a symbol or variable node contains the probability for each element of the Galois Field that the symbol or variable node has the value of that element. Thus, for a GF(q) decoder, a likelihood value for a symbol will contain q probabilities, giving the likelihoods that the symbol has the value of each of the q Galois Field elements. In the normalized format, the likelihood value contains a hard decision identifying the Galois Field element with the most likely value of the symbol, and probabilities for the values of the remaining Galois Field elements, each normalized to the likelihood of the most likely Galois Field element. Thus, for a GF(q) decoder, a normalized likelihood value for a symbol will contain a hard decision and q−1 probabilities, giving the most likely symbol value and the likelihoods that the symbol has the value of each of the remaining q Galois Field elements, normalized to the likelihood of the most likely element. In a decoder employing a min-sum decoding algorithm or a variation thereof, the q likelihoods in a likelihood value sum to 1, with the lowest being the most probable. In these embodiments, a normalized likelihood value can be represented as Q_{i,j}=[Q*_{i,j}(0), Q_{i,j}(1) . . . Q_{i,j}(q−1)], where Q*_{i,j}(0) is the hard decision identifying the most likely Galois Field element, and Q_{i,j}(1) . . . Q_{i,j}(q−1) are the probabilities for the values of the remaining Galois Field elements, each normalized to the likelihood of the most likely Galois

Field element, calculated by subtracting from each the likelihood of the most likely Galois Field element. In some embodiments, absolute likelihood values are ordered in vectors according to the element order in the Galois Field, while normalized likelihood values are ordered in vectors according to likelihood, with most likely Galois Field element value placed first in the vector and the least likely placed last.

For some embodiments of a GF(4) non-binary layered low density parity check decoder using log-likelihood ratios, the following table sets forth the hard decisions and normalized log likelihood ratios for the four possible symbol values from the Galois Field:

TABLE 1

| | HD | LLR0 | LLR1 | LLR2 |
|---|---|---|---|---|
| LLR related | 00 | 01 | 10 | 11 |
| to symbols | 01 | 00 | 11 | 10 |
| | 10 | 11 | 00 | 01 |
| | 11 | 10 | 01 | 00 |

where the three log likelihood ratio values LLR0, LLR1, LLR2 are calculated as follows:

if hd=00, LLR0=log(Probability(hd=01))−log(Probability(hd=00));

if hd=00, LLR1=log(Probability(hd=10))−log(Probability(hd=00));

if hd=00, LLR2=log(Probability(hd=11))−log(Probability(hd=00));

if hd=01, LLR0=log(Probability(hd=00))−log(Probability(hd=01));

if hd=01, LLR1=log(Probability(hd=11))−log(Probability(hd=01));

if hd=01, LLR2=log(Probability(hd=10))−log(Probability(hd=01));

if hd=10, LLR0=log(Probability(hd=11))−log(Probability(hd=10));

if hd=10, LLR1=log(Probability(hd=00))−log(Probability(hd=10));

if hd=10, LLR2=log(Probability(hd=01))−log(Probability(hd=10));

if hd=11, LLR0=log(Probability(hd=10))−log(Probability(hd=11));

if hd=11, LLR1=log(Probability(hd=01))−log(Probability(hd=11));

if hd=11, LLR2=log(Probability(hd=00))−log(Probability(hd=11));

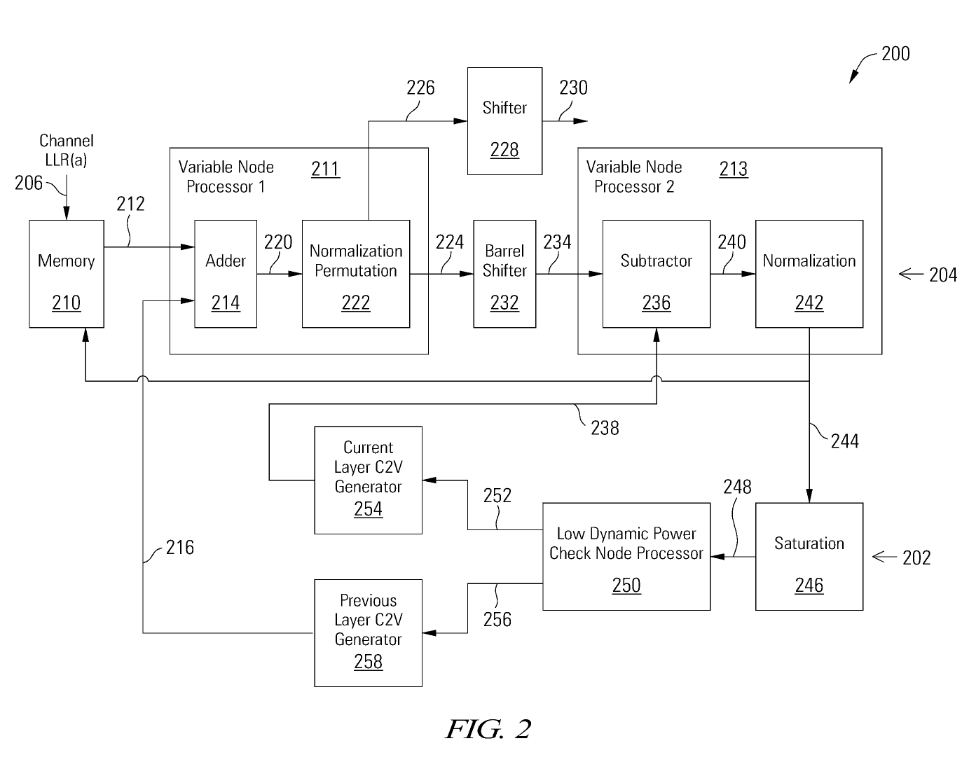

Turning to FIG. 2, a non-binary layered min-sum based low density parity check decoder 200 with a low dynamic power check node processor 202 is illustrated in block-diagram form in accordance with one or more embodiments of the present invention. Incoming likelihood values for data to be decoded are received at input 206 and stored in a decoder input buffer or memory 210 as initial Q messages, or variable node to check node messages. In some embodiments, the likelihood values include a hard decision and soft data. As used herein, the phrase “soft data” is used in its broadest sense to mean reliability data with each instance of the reliability data indicating a likelihood that a symbol has been correctly detected. In some embodiments of the present invention, the soft data or reliability data is log likelihood ratio data as is known in the art. In some embodiments, the likelihood values are log likelihood ratios. In some embodiments of a non-binary layered low density parity check decoder 200 with low dynamic power check node processor 202, the input 206 receives normalized likelihood values, and a decoder output 230 yields normalized likelihood values.

The memory 210 yields stored Q messages 212 for the layer previous to the layer currently being processed, also referred to herein as the previous layer and the connected layer. The stored Q messages 212 are therefore either initialized by channel likelihood values or calculated in a previous or earlier decoding iteration, and are therefore old Q messages.

An adder 214 adds the Q messages 212 to previous layer check node to variable node messages or new R messages 216, yielding a sum or S messages 220 containing total likelihood values for the previous layer. Again, columns in the H matrix represent variable nodes, and by adding all the non-zero entries in a column, the connected variable nodes are added to yield the input to a check node. The adder 214 can comprise any suitable circuitry for adding likelihood values, operating in array fashion in some embodiments. Based upon the disclosure provided herein, one of ordinary skill in the art will recognize a variety of circuits that may be included in adder 214.

The S messages 220 are provided to a normalization and permutation circuit 222, which converts the format of the S messages 220 from four soft LLR values to the equivalent content but different format of one hard decision and four soft LLR values (for a GF(4) embodiment), and which applies a permutation to rearrange the variable node updated values to prepare for the check node update and to apply the permutations specified by the non-zero elements of the H matrix. Based upon the disclosure provided herein, one of ordinary skill in the art will recognize a variety of circuits that may be included in rearranging circuit 220, such as lookup circuits. For example, in a GF(4) embodiment in which the four elements 0-3 of the Galois Field are 0, 1, α, α², the multiplication in the Galois Field can be performed by normalization and permutation circuit 222 as follows. Element 2 (α) multiplied by element 1 (1) equals α×1 or α, which is element 2. Similarly, element 2×2=α×α=α², which is element 3. Element 2×3=α×α²=1, which is element 1. Thus, element 2 multiplied by either 1, 2 and 3 results in elements 2, 3, and 1, respectively, which are permutations of elements 1, 2 and 3. The normalization and permutation circuit 222 yields P messages 224 for the previous layer at the output of the first part 211 of the variable node processor 204. The P messages 224 are in absolute format.

The normalization and permutation circuit 222 also yields soft LLR values 226 which are provided to a cyclic shifter 228. Cyclic shifter 228 rearranges the soft LLR values 226 to column order, performs a barrel shift which shifts the normalized soft LLR values 226 from the previous layer to the current layer, and yields hard decisions 230 or aₙ*, calculated as argminₐ Sₙ(a).

The P messages 224 from the normalization and permutation circuit 222 are provided to a barrel shifter 232, a cyclic shifter which shifts the symbol values in the normalized LLR P messages 224 to generate the next circulant sub-matrix, yielding current layer P messages 234 which contain the total soft LLR values of the current layer.

The current layer P messages 234 are provided to a subtractor 236 which subtracts the current layer check node to variable node messages, or old R messages 238, from the current layer P messages 234, yielding current layer D messages 240. The current layer check node to variable node messages or old R messages 238 are old values for the current layer, generated during a previous decoding iteration. Generally, the vector message from a check node to a variable node contains the probabilities for each symbol d in the Galois Field that the destination variable node contains that symbol d, based on the prior round variable node to check node messages from neighboring variable nodes other than the destination variable node. The inputs from neighboring variable nodes used in a check node to generate the check node to variable node message for a particular neighboring variable node are referred to as extrinsic inputs and include the prior round variable node to check node messages from all neighboring variable nodes except the particular neighboring variable node for which the check node to variable node message is being prepared, in order to avoid positive feedback. The check node prepares a different check node to variable node message for each neighboring variable node, using the different set of extrinsic inputs for each message based on the destination variable node. Subtracting the current layer check node to variable node messages or old R messages 238 from an earlier iteration removes the intrinsic input, leaving only the extrinsic inputs to generate a check node to variable node message for a variable node. The subtractor 236 can comprise any suitable circuitry for subtracting likelihood values. Based upon the disclosure provided herein, one of ordinary skill in the art will recognize a variety of circuits that can be included in subtractor 236.

D messages 240 are provided to a normalizing circuit 242 which converts the format of the D messages 240 from absolute format to normalized format, yielding new Q messages 244 in normalized format. The new Q messages 244 are output from the second part 213 of the variable node processor 204 and stored in memory 210 for subsequent decoding iterations, overwriting previous channel or calculated values for the current layer.

The new Q messages 244 are processed in a low dynamic power check node processor 202 to generate old R messages 238 and new R messages 216 using a min-sum based algorithm. The new Q messages 244 are provided to a saturation circuit 246 in the low dynamic power check node processor 202 which reduces the precision of the new Q messages 244, yielding saturated Q messages 248. The saturation circuit 246 also aids in reducing dynamic power consumption in the check node processor 202 by enabling a reduction of switching when detecting the minimum and next minimum values, saturating the new Q messages 244 to the next minimum values.

A minimum and next minimum finder circuit 250 in the low dynamic power check node processor 202 calculates the minimum value min₁(d), the second or next minimum value min₂(d) and the index of the minimum value idx(d) for each of the q symbols in the Galois Field, based on sub-messages Q_{i,jk}(d) in the message vectors from each neighboring variable node yielding results generally according to the following logic:

if min₁(d)>Q_{i,jk}(d),
idx(d)=i;
min₂(d)=min₁(d);
min₁(d)=Q_{i,jk}(d);

else
idx(d)=idx(d);
min₂(d)=min(min₂(d), Q_{i,jk}(d));

The minimum and next minimum finder circuit 250 also calculates the signs of the saturated Q messages 248 and tracks the sign value of each non-zero element of the H matrix and the cumulative sign for the current layer. Given the min-sum results 252 containing the current layer minimum, next minimum and index values with the sign values, calculated in the previous local decoding iteration (thus old), a current layer C2V generator 254 calculates the current layer check node to variable node messages or old R messages 238. Given the min-sum results 256 containing the previous layer minimum, next minimum and index values with the sign values, calculated in the current local decoding iteration (thus new), the a previous layer C2V generator 258 calculates the previous layer check node to variable node messages or new R messages 216.

As will be disclosed in more detail below, the low dynamic power check node processor 202 reduces switching activities after the minimum (M1) and next minimum (M2) values have been found, thereby reducing dynamic power usage which depends directly on circuit switching activities. For example, if the first Nth variable nodes already give the minimum and next minimum for the whole codeword, any comparison and data switching or multiplexing after the Nth variable node would be wasted power. In the low dynamic power check node processor 202, no further operations are needed when the Q input is not smaller than M2. The Q values are saturated to M2 in saturation circuit 260, which introduces new comparators to compare the Q values to M2, but the comparison results can be reused in the data multiplexing in the minimum and next minimum finder circuit 250. The minimum and next minimum finder circuit 250 is adapted as described below to eliminate further switching after the minimum and next minimum values have been found.

The variable node processor 204 and the low dynamic power check node processor 202 thus operate together to perform layered decoding of non-binary data. The variable node processor 204 generates variable node to check node messages 244 and calculates perceived values based on check node to variable node messages in old R messages 238 and new R messages 216. The term “perceived value” is used herein to refer to the value of symbols to be decoded, and in some embodiments, is represented by likelihood values. The low dynamic power check node processor 202 generates check node to variable node messages 238, 316 and calculates checksums based on variable node to check node messages 244. During operation of the low density parity check layer decoder 200, as Q values and R values are iteratively circulated through the decoder 200, parity checks are calculated based on decoder output 230. If the number of unsatisfied parity checks is equal to zero after all layers have been processed, the low density parity check layer decoder 200 has converged and processing can be halted.

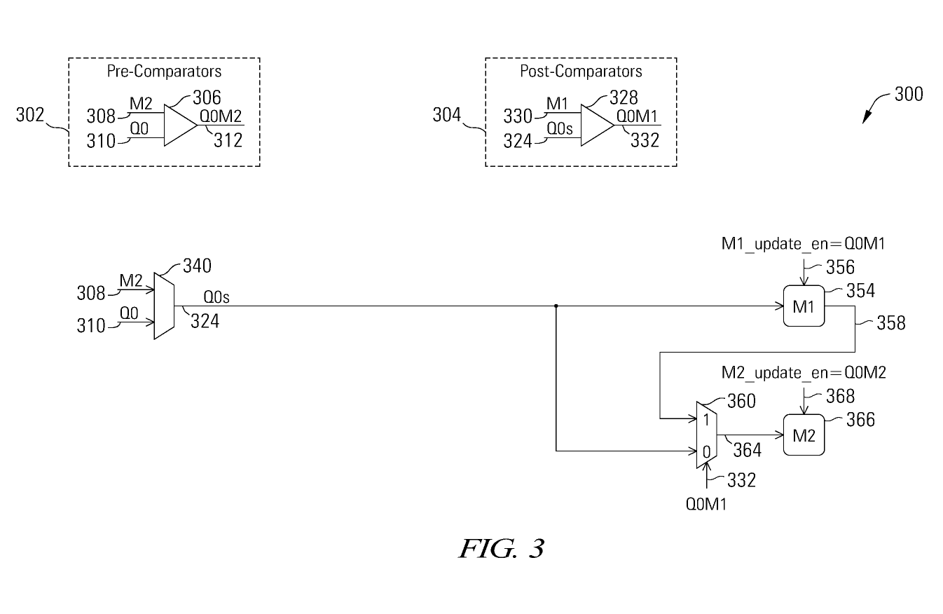

Turning now to FIG. 3, a low dynamic power check node processor 300 suitable for use in a min-sum based low density parity check decoder with a single data path such as that of FIG. 2 is depicted in accordance with one or more embodiments of the present invention. The low dynamic power check node processor 300 gathers all the Q information from variable nodes which connect to a same check node, finds and records the minimum Q value M1 and its variable node index, and finds and records the next or second minimum Q value M2. In the block diagram of FIG. 3, a saturation circuit 340 and a minimum and next minimum finder circuit are both included, although the functions can be separated or performed in any suitable division of circuitry.

A pre-comparator block 302 includes a comparator 306 that determines whether the input data value Q0 310 is less than the current value of the second minimum M2 308. The signal Q0M2 312 is asserted by the comparator 306 when Q0<M2.

Saturation circuit 340 receives the current value of the second minimum M2 308 and the current input data value Q0 310, and outputs the saturated data value Q0s 324, saturated to the current value of the second minimum M2 308. The saturation circuit 340 reduces the precision of Q value, for example receiving a 7-bit Q value and outputting a 5-bit Q value, such that the saturated data value Q0s 324 is not larger than the second minimum M2 308.

A post comparator block 304 includes a comparator 328 that determines whether the saturated data value Q0s 324 is less than the minimum value M1 330. The signal Q0M1 332 is asserted by the comparator 328 when Q0s<M1.

A minimum value register 354 is controlled by an M1_update_en signal 356, replacing the previous minimum value with the saturated data value Q0s 324 when Q0M1 332 is asserted. In other words, when the saturated data value Q0s 324 is less than the previous minimum value, the previous minimum value in the minimum value register 354 is overwritten by the smaller saturated data value Q0s 324.

A switch or multiplexer 360, controlled by the Q0M1 signal 332, selects as output 364 the previous minimum value M1 358 when Q0M1 332 is asserted, and the saturated data value Q0s 324 when Q0M1 332 is not asserted. In other words, the greater of the saturated data value Q0s 324 and the previous minimum value M1 is selected as the output of the multiplexer 360.

A second minimum value register 366 is controlled by an M2_update_en signal 368, replacing the previous second minimum value with output of the multiplexer 360 when Q0M2 312 is asserted. In other words, when the saturated data value Q0s 324 is less than the previous second minimum value, the previous second minimum value in the second minimum value register 366 is overwritten by the greater of the saturated data value Q0s 324 and the previous minimum value M1.

Thus, during operation, if the saturated data value Q0s 324 is lower than the previous minimum value M1, the saturated data value Q0s 324 is used as the new minimum value M1 value and the previous minimum value M1 is used as the new second minimum value M2. If the saturated data value Q0s 324 is greater than the previous minimum value M1 but less than the previous second minimum value M2, the saturated data value Q0s 324 is used as the new second minimum value M2 and the previous minimum value M1 is left unchanged.

Notably, all of the comparison and switching circuitry downstream from the saturated data value Q0s 324 in the low dynamic power check node processor 300, including the post-comparators 304, is disabled in some embodiments when the pre-comparators 302 determine that the input data value Q0 310 is not less than the current value of the second minimum M2 308. Thus, if the previous minimum value M1 and the previous second minimum value M2 are already smaller than the input data value Q0 310, no changes need to be made and dynamic power usage is reduced by eliminating further comparison and switching operations in the low dynamic power check node processor 300.

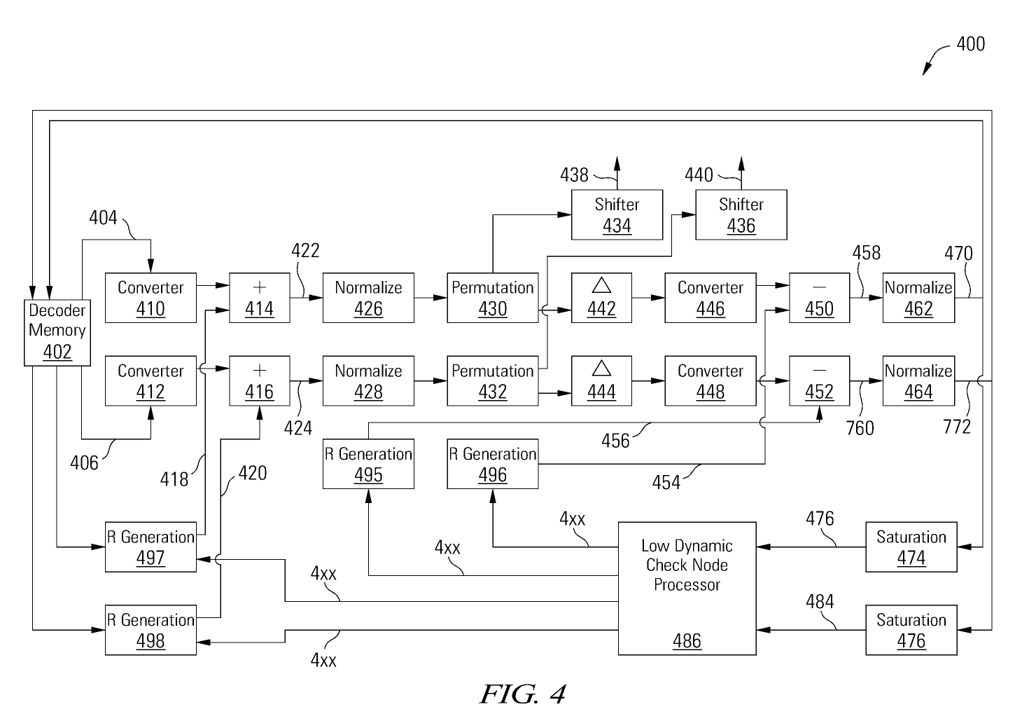

Turning to FIG. 4, a min-sum based non-binary layered low density parity check decoder 400 with a low dynamic power check node processor 486 is depicted in accordance with some embodiments of the present invention. In this example embodiment, two circulants are processed in parallel, providing two pieces of check node to variable node data to the check node processor 486 at every clock. A decoder memory 402 stores soft LLR input values, and Q values. The decoder memory 402 is a ping pong memory. The decoder memory 402 provides Q values 404 and 406 of the connected (or previous) layer to converters 410 and 412, respectively, each based on a different circulant being processed. In a GF(4) embodiment, the Q values 404 and 406 each consist of one hard decision and three soft LLR values.

The converters 410 and 412 convert the Q values from a format containing a hard decision and three soft LLR values to a format containing four soft LLR values, with the information being equivalent in the two formats. Adders 414 and 416 add the connected layer's Q value (converted by converters 410 and 412) to the connected layer's R value 418 and 420 of each symbol of a circulant respectively, yielding the soft LLR values or S messages 422 and 424 of each symbol. In an embodiment with GF(4), each adder 414 and 416 consists of four adders each, adapted to add the connected layer's Q value with the connected layer's R value of each symbol of a circulant respectively to obtain the soft LLR values or S messages 422 and 424 of each symbol.

The S messages 422 and 424 of each symbol are provided to normalizers 426 and 428, which compare the four values in each of the soft LLR values 422 and 424 to identify the minimum of each, and which subtract that minimum from the other three soft LLR values, thereby normalizing each of the soft LLR values 422 and 424 to their respective minimum.

The normalized variable node LLR values from normalizers 426 and 428 are provided to permutation circuits 430 and 432, which rearrange the variable node updated values to prepare for the check node update and apply the permutations specified by the non-zero elements of the H matrix.

Shifters 434 and 436 process the output of permutation circuits 430 and 432 to shift the soft LLR values back to column order to yield soft LLR outputs 438 and 440 as the hard decision output of the decoder 400. Shifters 434 and 436 are used to shift from row order to column order because the low density parity check layer decoder 400 processes data in row order, but the output total soft LLR is ordered by column in order to subtract the input LLR which is in column order to yield the extrinsic LLR value. Delta shifters 442 and 444 also process the output of permutation circuits 430 and 432, shifting the output of the permutation circuits 430 and 432 by the difference in the circulant shift numbers of the current layer and the connected layer. In a given column there are circulants with different shift numbers, and the delta shifters 442 and 444 compensate for the different shift numbers of the current layer and the connected layer.

The output of delta shifters 442 and 444 is provided to converters 446 and 448 which convert from the format containing one hard decision and three soft LLR values back to the format containing four soft LLR values. Subtractors 450 and 452 then subtract the R values 454 and 456 of the symbols of the current layer from the soft LLR P values provided by converters 446 and 448 to obtain Q values 458 and 460 of the symbols of the current layer. The Q values 458 and 460 of the symbols of the current layer are then normalized in normalizers 462 and 464, which compare the four values in each of the Q values 458 and 460 to identify the minimum of each, and which subtract that minimum from the other three elements of the Q values 458 and 460, thereby normalizing each of the Q values 458 and 460 to their respective minimum. The normalized Q values 470 and 472 are provided to the decoder memory 402 to update the Q values of the current layers.

A low dynamic power check node processor 480 processes the normalized Q values 470, 472 to generate connected layer R values 418, 420 and current layer R values 454, 456 using saturation circuits 474, 476, a minimum and next minimum finder circuit 486 and R generation circuits 495, 496, 497, 498. The normalized Q values 470 and 472 are provided to the saturation circuits 474, 476 which reduce the precision of the normalized Q values 470, 472, yielding saturated normalized Q values 482, 484. The saturation circuits 474, 476 also aid in reducing dynamic power consumption in the minimum and next minimum finder circuit 486 by enabling a reduction of switching when detecting the minimum and next minimum values by saturating the normalized Q messages 482, 484 to the next minimum values.

The minimum and next minimum finder circuit 486 in the low dynamic power check node processor 480 calculates the minimum value, the second or next minimum value and the index of the minimum value for each of the q symbols in the Galois Field. The minimum and next minimum finder circuit 486 also calculates the signs of the saturated normalized Q values 482, 484 and tracks the sign value of each non-zero element of the H matrix and the cumulative sign for the current layer.

As will be disclosed in more detail below, the low dynamic power check node processor 480 reduces switching activities after the minimum (M1) and next minimum (M2) values have been found, thereby reducing dynamic power usage which depends directly on circuit switching activities. For example, if the first Nth variable nodes already give the minimum and next minimum for the whole codeword, any comparison and data switching or multiplexing after the Nth variable node would be wasted power. In the low dynamic power check node processor 202, no further operations are needed when the Q input is not smaller than M2. The Q values are saturated to M2 in saturation circuits 474, 476, which introduces new comparators to compare the Q values to M2, but the comparison results can be reused in the data multiplexing in the minimum and next minimum finder circuit 486. The minimum and next minimum finder circuit 486 is adapted as described below to eliminate further switching after the minimum and next minimum values have been found.

The min-sum results 490, 491, 492, 493 containing the current and connected layer minimum, next minimum and index values with sign values are provided to two sets of R generators 495, 496, 497 and 498, which generate the R values for the connected layer or current layer. R generators 495 and 496 generate the R values for the current layer of the two circulants being processed, and R generators 497 and 498 generate the R values for the connected layer of the two circulants being processed. If the current column index is equal to the index of the minimum value, then the value of R is the second minimum value. Otherwise, the value of R is the minimum value of that layer. The sign of R is the XOR of the cumulative sign and the current sign of the symbol.

During operation of the low density parity check layer decoder 400, as Q values and R values are iteratively circulated through the decoder 400, parity checks are calculated based on soft LLR outputs 438 and 440. If the number of unsatisfied parity checks is equal to zero after all layers have been processed, the low density parity check layer decoder 400 has converged and processing can be halted.

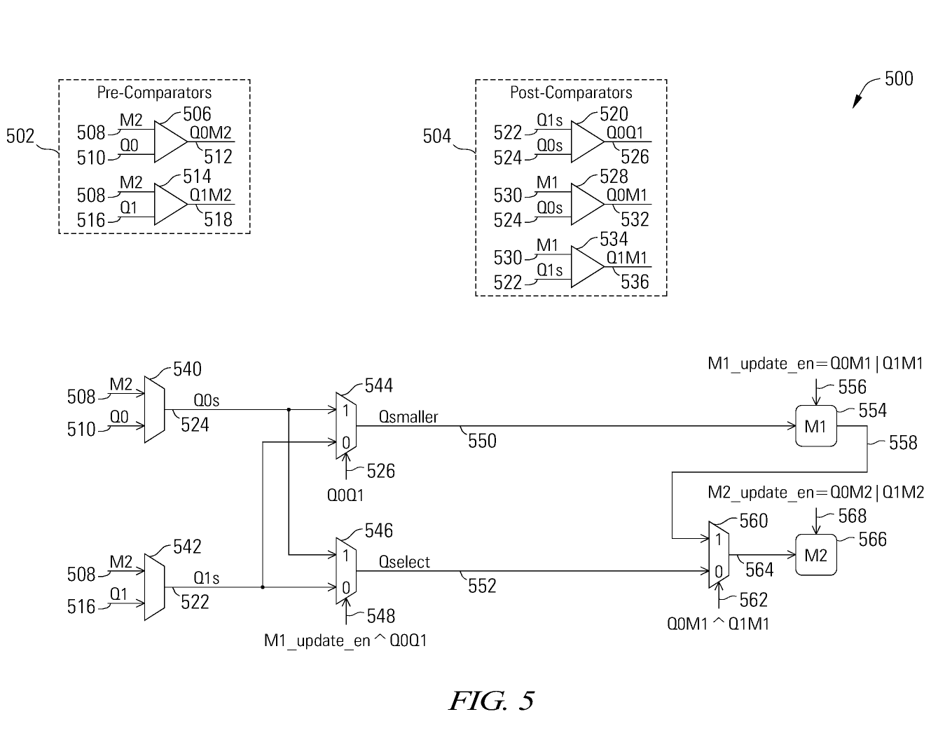

Turning now to FIG. 5, a low dynamic power check node processor 500 suitable for use in a min-sum based low density parity check decoder with a dual data path such as that of FIG. 4 is depicted in accordance with one or more embodiments of the present invention. The low dynamic power check node processor 500 gathers all the Q information from variable nodes which connect to a same check node, operating on two data paths simultaneously, finds and records the minimum Q value M1 and its variable node index, and finds and records the next or second minimum Q value M2. In the block diagram of FIG. 5, saturation circuits 540, 542 and a minimum and next minimum finder circuit are both included, although the functions can be separated or performed in any suitable division of circuitry.

A pre-comparator block 502 includes a comparator 506 that determines whether the first input data value Q0 510 is less than the current value of the second minimum M2 508. The signal Q0M2 512 is asserted by the comparator 506 when Q0<M2. The pre-comparator block 502 includes a second comparator 514 that determines whether the second input data value Q1 516 is less than the current value of the second minimum M2 508. The signal Q1M2 518 is asserted by the comparator 514 when Q1<M2.

Saturation circuit 540 receives the current value of the second minimum M2 508 and the current first input data value Q0 510, and outputs the first saturated data value Q0s 524, saturated to the current value of the second minimum M2 508. The saturation circuit 540 reduces the precision of Q value, for example receiving a 7-bit Q value and outputting a 5-bit Q value, such that the first saturated data value Q0s 524 is not larger than the second minimum M2 508.

Saturation circuit 542 receives the current value of the second minimum M2 508 and the current second input data value Q1 516, and outputs the second saturated data value Q1s 522, saturated to the current value of the second minimum M2 508. The saturation circuit 542 reduces the precision of Q value, for example receiving a 7-bit Q value and outputting a 5-bit Q value, such that the second saturated data value Q1s 522 is not larger than the second minimum M2 508.

A post comparator block 504 includes a comparator 520 that determines whether the first saturated data value Q0s 524 is less than the second saturated data value Q1s 522. The signal Q0Q1 526 is asserted when Q0s<Q1s. The post comparator block 504 also includes a comparator 528 that determines whether the first saturated data value Q0s 524 is less than the minimum value M1 530. The signal Q0M1 532 is asserted by the comparator 528 when Q0s<M1. The post comparator block 504 also includes a comparator 534 that determines whether the second saturated data value Q1s 522 is less than the minimum value M1 530. The signal Q1M1 536 is asserted by the comparator 534 when Q1s<M1.

A switch or multiplexer 544, controlled by the Q0Q1 signal 526, selects as Qsmaller 550 the first saturated data value Q0s 524 when Q0Q1 526 is asserted and the second saturated data value Q1s 522 when Q0Q1 526 is not asserted. In other words, Qsmaller 550 is the smaller of the first saturated data value Q0s 524 and the second saturated data value Q1s 522.

A minimum value register 554 is controlled by an M1_update_en signal 556, replacing the previous minimum value with Qsmaller 550 when either or both Q0M1 532 or Q1M1 536 are asserted. In other words, when either the first saturated data value Q0s 524 or the second saturated data value Q1s 522 is less than the previous minimum value, the previous minimum value in the minimum value register 554 is overwritten by the smaller of the saturated data value Q0s 524 and the second saturated data value Q1s 522.

A switch or multiplexer 546, controlled by a control signal 548 which is the exclusive-OR of the M1_update_en signal 556 and the Q0Q1 signal 526, selects as Qselect 552 the first saturated data value Q0s 524 when the control signal 548 is asserted and the second saturated data value Q1s 522 when the control signal 548 is not asserted. In other words, Qselect 552 is the first saturated data value Q0s 524 when either the first minimum value M1 is updated or when the first saturated data value Q0s 524 is less than the second saturated data value Q1s 522, but not both.

A switch or multiplexer 560, controlled by a control signal 562 which is the exclusive OR of the Q0M1 signal 532 and the Q1M1 signal 536, selects as output 564 the previous minimum value M1 558 when the control signal 562 is asserted, and the Qselect signal 552 when the control signal 562 is not asserted.

A second minimum value register 566 is controlled by an M2_update_en signal 568, which in this embodiment is the OR of Q0M2 signal 512 and the Q1M2 signal 518, replacing the previous second minimum value with output of the multiplexer 560 when the M2_update_en signal 568 is asserted.

Thus, during operation, the minimum value M1 and the second minimum value M2 are updated based on the first saturated data value Q0s 524 and the second saturated data value Q1s 522 and on the previous values of the minimum value M1 and the second minimum value M2.

Notably, all of the comparison and switching circuitry downstream from the first saturated data value Q0s 524 and the second saturated data value Q1s 522 in the low dynamic power check node processor 500, including the post-comparators 504, is disabled when the pre-comparators 502 determine that neither the first saturated data value Q0s 524 nor the second saturated data value Q1s 522 are less than the current value of the second minimum M2 508.

Thus, if the previous minimum value M1 and the previous second minimum value M2 are already smaller than the first saturated data value Q0s 524 and the second saturated data value Q1s 522, no changes need to be made and dynamic power usage is reduced by eliminating further comparison and switching operations in the low dynamic power check node processor 500.

The low dynamic power check node processor can be adapted to any number of parallel data paths, such as the single path of FIGS. 2-3 or the dual path of FIGS. 4-5 or any other number of parallel data paths.

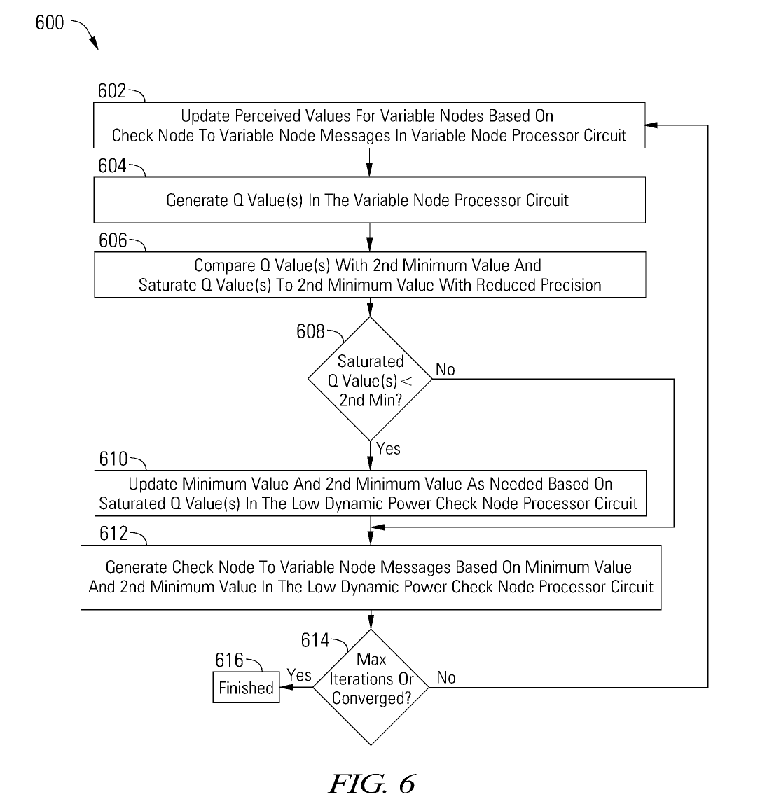

Turning to FIG. 6, a flow diagram 600 depicts a method for low density parity check decoding with a low dynamic power check node processor in accordance with one or more embodiments of the present invention. Following flow diagram 600, perceived values for variable nodes are updated based on check node to variable node messages in a variable node processor circuit. (Block 602) Q value(s) are generated in the variable node processor circuit. (Block 604) The Q value(s) are compared with the second minimum value and the Q value(s) are saturated to the second minimum value with reduced precision. (Block 606) A determination is made as to whether the Q value(s) are less than the second minimum value. (Block 608) If they are, the minimum value and second minimum value are updated as needed based on the saturated Q value(s) in the low dynamic power check node processor. (Block 610) Otherwise, the minimum value and second minimum value are left unchanged, preventing further comparison and switching in the low dynamic power check node processor. The operations of blocks 606-610 are performed for each of the check nodes in the codeword, gathering the Q value(s) for the variable nodes which connect to each of the check nodes. Check node to variable node messages are generated based on the minimum value and the second minimum value in the low dynamic power check node processor. (Block 612) A determination is made as to whether the maximum number of iterations has been reached in the decoder or whether the decoder has converged. (Block 614) If so, decoding is finished. (Block 616) If not, decoding continues at block 602.

Although the low density parity check decoder with low dynamic power check node processor disclosed herein is not limited to any particular application, several examples of applications are presented herein that benefit from embodiments of the present invention. Turning to FIG. 7, a read channel 700 with a low density parity check decoder with low dynamic power check node processor 740 is depicted in accordance with one or more embodiments of the present invention. The read channel 700 is used to process an analog signal 702 and to retrieve user data bits from the analog signal 702 without errors. In some cases, analog signal 702 is derived from a read/write head assembly in a magnetic storage medium. In other cases, analog signal 702 is derived from a receiver circuit that is operable to receive a signal from a transmission medium. The transmission medium may be wireless or wired such as, but not limited to, cable or optical connectivity. Based upon the disclosure provided herein, one of ordinary skill in the art will recognize a variety of sources from which analog signal 702 can be derived.

The read channel 700 includes an analog front end 704 that receives and processes the analog signal 702. Analog front end 704 may include, but is not limited to, an analog filter and an amplifier circuit as are known in the art. Based upon the disclosure provided herein, one of ordinary skill in the art will recognize a variety of circuitry that may be included as part of analog front end 704. In some cases, the gain of a variable gain amplifier included as part of analog front end 704 may be modifiable, and the cutoff frequency and boost of an analog filter included in analog front end 704 may be modifiable. Analog front end 704 receives and processes the analog signal 702, and provides a processed analog signal 706 to an analog to digital converter 710.

Analog to digital converter 710 converts processed analog signal 706 into a corresponding series of digital samples 712. Analog to digital converter 710 may be any circuit known in the art that is capable of producing digital samples corresponding to an analog input signal. Based upon the disclosure provided herein, one of ordinary skill in the art will recognize a variety of analog to digital converter circuits that may be used in relation to different embodiments of the present invention. In other embodiments, digital data is retrieved directly from a storage device or other source, such as a flash memory. Digital samples 712 are provided to an equalizer 714. Equalizer 714 applies an equalization algorithm to digital samples 712 to yield an equalized output 716. In some embodiments of the present invention, equalizer 714 is a digital finite impulse response filter circuit as is known in the art. Data or codewords contained in equalized output 716 may be stored in a buffer 720 until a data detector 724 is available for processing and ready to receive stored equalized samples 722.

The data detector 724 performs a data detection process on the received input, resulting in a detected output 726. In some embodiments of the present invention, data detector 724 is a Viterbi algorithm data detector circuit, or more particularly in some cases, a maximum a posteriori (MAP) data detector circuit as is known in the art. In these embodiments, the detected output 726 contains log likelihood ratio information about the likelihood that each bit or symbol has a particular value. Based upon the disclosure provided herein, one of ordinary skill in the art will recognize a variety of data detectors that may be used in relation to different embodiments of the present invention. Data detector 724 is started based upon availability of a data set in buffer 720 from equalizer 714 or another source.

The detected output 726 from data detector 724 is provided to an interleaver 730 that protects data against burst errors. Burst errors overwrite localized groups or bunches of bits. Because low density parity check decoders are best suited to correcting errors that are more uniformly distributed, burst errors can overwhelm low density parity check decoders. The interleaver 730 prevents this by interleaving or shuffling the detected output 726 from data detector 724 to yield an interleaved output 732 which is stored in a memory 734. The interleaved output 736 from the memory 734 is provided to a low density parity check decoder with low dynamic power check node processor 740 which performs parity checks on the interleaved output 736, ensuring that parity constraints established by a low density parity check encoder (not shown) before storage or transmission are satisfied in order to detect and correct any errors that may have occurred in the data during storage or transmission.

Multiple detection and decoding iterations may be performed in the read channel 700, referred to herein as global iterations. (In contrast, local iterations are decoding iterations performed within the low density parity check decoder with low dynamic power check node processor 740.) To perform a global iteration, likelihood values 742 from the non-binary layered low density parity check decoding with normalized input and output 740 are stored in memory 734, deinterleaved in a deinterleaver 746 to reverse the process applied by interleaver 730, and provided again to the data detector 724 to allow the data detector 724 to repeat the data detection process, aided by the log likelihood ratio values 742 from the low density parity check decoder with low dynamic power check node processor 740. In this manner, the read channel 700 can perform multiple global iterations, allowing the data detector 724 and low density parity check decoder 740 to converge on the correct data values.

The low density parity check decoder 740 also produces hard decisions 752 about the values of the data bits or symbols contained in the interleaved output 732 of the interleaver 730. The hard decisions 752 from the low density parity check decoder 740 are deinterleaved in a hard decision deinterleaver 754, reversing the process applied in interleaver 730, and stored in a hard decision memory 760 before being provided to a user or further processed. For example, the output 762 of the read channel 700 can be further processed to reverse formatting changes applied before storing data in a magnetic storage medium or transmitting the data across a transmission channel.

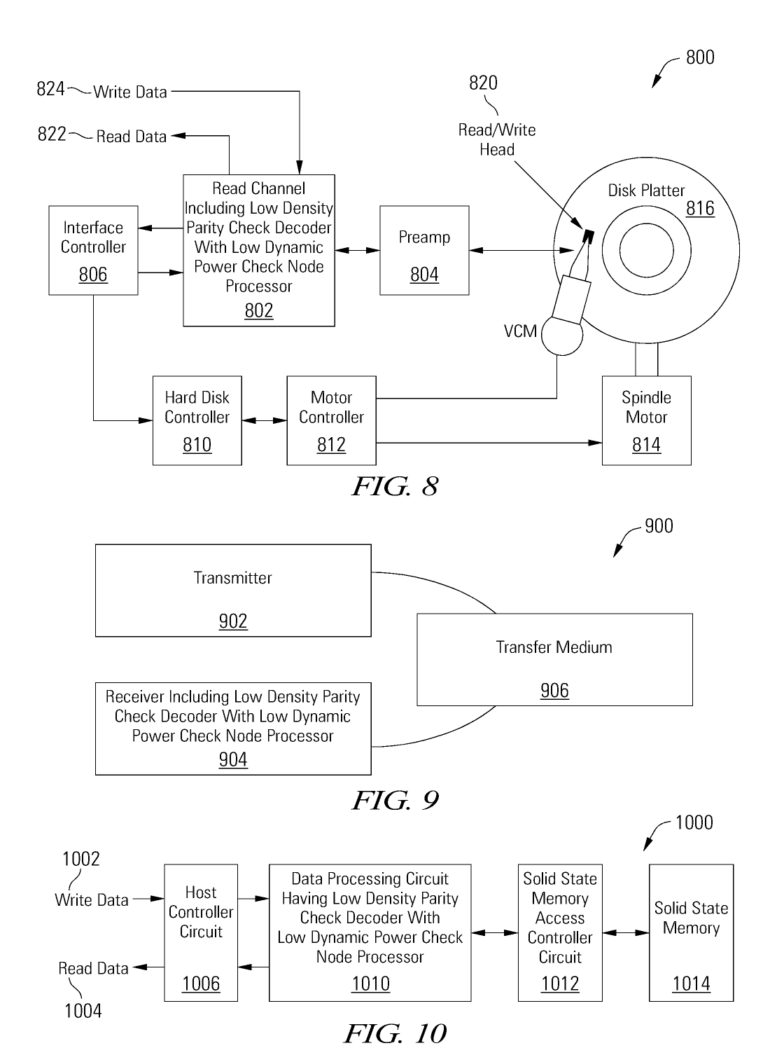

Turning to FIG. 8, a storage system 800 is illustrated as an example application of a low density parity check decoder with low dynamic power check node processor in accordance with some embodiments of the present invention. The storage system 800 includes a read channel circuit 802 with a low density parity check decoder with low dynamic power check node processor in accordance with one or more embodiments of the present invention. Storage system 800 may be, for example, a hard disk drive. Storage system 800 also includes a preamplifier 804, an interface controller 806, a hard disk controller 810, a motor controller 812, a spindle motor 814, a disk platter 816, and a read/write head assembly 820. Interface controller 806 controls addressing and timing of data to/from disk platter 816. The data on disk platter 816 consists of groups of magnetic signals that may be detected by read/write head assembly 820 when the assembly is properly positioned over disk platter 816. In one embodiment, disk platter 816 includes magnetic signals recorded in accordance with either a longitudinal or a perpendicular recording scheme.

In a typical read operation, read/write head assembly 820 is accurately positioned by motor controller 812 over a desired data track on disk platter 816. Motor controller 812 both positions read/write head assembly 820 in relation to disk platter 816 and drives spindle motor 814 by moving read/write head assembly 820 to the proper data track on disk platter 816 under the direction of hard disk controller 810. Spindle motor 814 spins disk platter 816 at a determined spin rate (RPMs). Once read/write head assembly 820 is positioned adjacent the proper data track, magnetic signals representing data on disk platter 816 are sensed by read/write head assembly 820 as disk platter 816 is rotated by spindle motor 814. The sensed magnetic signals are provided as a continuous, minute analog signal representative of the magnetic data on disk platter 816. This minute analog signal is transferred from read/write head assembly 820 to read channel circuit 802 via preamplifier 804. Preamplifier 804 is operable to amplify the minute analog signals accessed from disk platter 816. In turn, read channel circuit 802 digitizes the received analog signal and decodes the digital data in a low density parity check decoder with low dynamic power check node processor to recreate the information originally written to disk platter 816. This data is provided as read data 822 to a receiving circuit. A write operation is substantially the opposite of the preceding read operation with write data 824 being provided to read channel circuit 802. This data is then encoded and written to disk platter 816.

It should be noted that storage system 800 may be integrated into a larger storage system such as, for example, a RAID (redundant array of inexpensive disks or redundant array of independent disks) based storage system. Such a RAID storage system increases stability and reliability through redundancy, combining multiple disks as a logical unit. Data may be spread across a number of disks included in the RAID storage system according to a variety of algorithms and accessed by an operating system as if it were a single disk. For example, data may be mirrored to multiple disks in the RAID storage system, or may be sliced and distributed across multiple disks in a number of techniques. If a small number of disks in the RAID storage system fail or become unavailable, error correction techniques may be used to recreate the missing data based on the remaining portions of the data from the other disks in the RAID storage system. The disks in the RAID storage system may be, but are not limited to, individual storage systems such storage system 800, and may be located in close proximity to each other or distributed more widely for increased security. In a write operation, write data is provided to a controller, which stores the write data across the disks, for example by mirroring or by striping the write data. In a read operation, the controller retrieves the data from the disks. The controller then yields the resulting read data as if the RAID storage system were a single disk.

In addition, it should be noted that storage system 800 may be modified to include solid state memory that is used to store data in addition to the storage offered by disk platter 816. This solid state memory may be used in parallel to disk platter 816 to provide additional storage. In such a case, the solid state memory receives and provides information directly to read channel circuit 802. Alternatively, the solid state memory may be used as a cache where it offers faster access time than that offered by disk platter 816. In such a case, the solid state memory may be disposed between interface controller 806 and read channel circuit 802 where it operates as a pass through to disk platter 816 when requested data is not available in the solid state memory or when the solid state memory does not have sufficient storage to hold a newly written data set. Based upon the disclosure provided herein, one of ordinary skill in the art will recognize a variety of storage systems including both disk platter 816 and a solid state memory.

Turning to FIG. 9, a wireless communication system 900 or data transmission device including a receiver 904 with a low density parity check decoder with low dynamic power check node processor is shown in accordance with some embodiments of the present invention. The transmitter 902 is operable to transmit encoded information via a transfer medium 906 as is known in the art. The encoded data is received from transfer medium 906 by receiver 904. Receiver 904 incorporates a low density parity check decoder with low dynamic power check node processor.

Turning to FIG. 10, another storage system 1000 is shown that includes a data processing circuit 1010 having a low density parity check decoder with low dynamic power check node processor in accordance with one or more embodiments of the present invention. A host controller circuit 1006 receives data to be stored (i.e., write data 1002). This data is provided to data processing circuit 1010 where it is encoded using a low density parity check encoder. The encoded data is provided to a solid state memory access controller circuit 1012. Solid state memory access controller circuit 1012 can be any circuit known in the art that is capable of controlling access to and from a solid state memory. Solid state memory access controller circuit 1012 formats the received encoded data for transfer to a solid state memory 1014. Solid state memory 1014 can be any solid state memory known in the art. In some embodiments of the present invention, solid state memory 1014 is a flash memory. Later, when the previously written data is to be accessed from solid state memory 1014, solid state memory access controller circuit 1012 requests the data from solid state memory 1014 and provides the requested data to data processing circuit 1010. In turn, data processing circuit 1010 decodes the received data using a low density parity check decoder with low dynamic power check node processor. The decoded data is provided to host controller circuit 1006 where it is passed on as read data 1004.

It should be noted that the various blocks discussed in the above application may be implemented in integrated circuits along with other functionality. Such integrated circuits may include all of the functions of a given block, system or circuit, or a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some cases, parts of a given system, block or circuit may be implemented in software or firmware, while other parts are implemented in hardware.

In conclusion, embodiments of the present invention provide novel systems, devices, methods and arrangements for low density parity check decoding with a low dynamic power check node processor. While detailed descriptions of one or more embodiments of the invention have been given above, various alternatives, modifications, and equivalents will be apparent to those skilled in the art without varying from the spirit of the invention. Therefore, the above description should not be taken as limiting the scope of embodiments of the invention which are encompassed by the appended claims.

What is claimed is:

1. A low density parity check decoder comprising:
a variable node processor, wherein the variable node processor is operable to generate variable node to check node messages and to calculate perceived values based on check node to variable node messages;
a saturation circuit operable to reduce a precision in the variable node to check node messages; and
a check node processor operable to generate the check node to variable node messages based on the variable node to check node messages at least in part by finding a minimum value, an index of the minimum value and a next minimum value of Q values in the variable node to check node messages, wherein the check node processor comprises a switching circuit operable to update the minimum and the next minimum values, and wherein the check node processor is operable to disable the switching circuit based at least in part on a comparison between the Q values and the next minimum value.

2. The low density parity check decoder of claim 1, wherein the check node processor is operable to reduce dynamic power usage by disabling the switching circuit when the Q values are not less than the next minimum value.

3. The low density parity check decoder of claim 1, wherein the saturation circuit is operable to saturate the Q values in the variable node to check node messages to the next minimum value.

4. The low density parity check decoder of claim 1, wherein the check node processor is operable to update the minimum value and the next minimum value when one of the Q values is smaller than the minimum value.

5. The low density parity check decoder of claim 1, wherein the check node processor is operable to update the next minimum value when one of the Q values is smaller than the next minimum value.

6. The low density parity check decoder of claim 1, wherein the low density parity check decoder processes one Q value at a time.

7. The low density parity check decoder of claim 1, wherein the low density parity check decoder processes multiple Q values at a time.

8. The low density parity check decoder of claim 1, wherein the variable node processor and check node processor are non-binary.

9. The low density parity check decoder of claim 1, wherein the check node processor is operable to find the minimum value, the index of the minimum value and the next minimum value of Q values for all variable nodes connected to a same check node.

10. The low density parity check decoder of claim 1, wherein the low density parity check decoder comprises a layer decoder.

11. The low density parity check decoder of claim 1, wherein the low density parity check decoder is implemented as an integrated circuit.

12. The low density parity check decoder of claim 1, wherein the low density parity check decoder is incorporated in a storage device.

13. The low density parity check decoder of claim 1, wherein the low density parity check decoder is incorporated in a transmission system.

14. A method of decoding data in a low density parity check decoder, comprising:
generating variable node to check node messages based on perceived values of variable nodes in an H matrix;
generating check node to variable node messages based on the variable node to check node messages by finding a minimum and a second minimum of Q values in the variable node to check node messages; and
updating the perceived values of the variable nodes based on the check node to variable node messages, wherein finding the minimum and the second minimum comprises:
comparing the Q values to the second minimum; and
where the Q values are not less than the second minimum, disabling switching circuits for finding the minimum and a second minimum.

15. The method of claim 14, wherein finding the minimum and the second minimum comprises operating the switching circuits to update the minimum and the second minimum when the Q values are less than the second minimum.

16. The method of claim 14, wherein generating the check node to variable node messages further comprises saturating the Q values to the second minimum.

17. The method of claim 14, wherein saturating the Q values to the second minimum comprises reducing a precision of the Q values.

18. The method of claim 14, wherein the method of decoding data comprises a layer decoding operation.

19. A low density parity check decoder comprising:
variable node processing means for updating variable node values based on check node to variable node messages and for generating variable node to check node messages; and
min-sum based check node processing means for generating the check node to variable node messages based on the variable node to check node messages by finding a minimum and a second minimum of Q values in the variable node to check node messages, wherein switching circuits in the min-sum based check node processing means are not operated when the Q values are not less than the second minimum.

20. The low density parity check decoder of claim 19, wherein the min-sum based check node processing means comprise means for saturating the Q values to the second minimum.
